(19) United States
(12) Patent Application Publication
(10) Pub. No.: US 2026/0231775 A1
(43) Pub. Date: Aug. 6, 2026

(54) SEMICONDUCTOR PACKAGE

(71) Applicant: SAMSUNG ELECTRONICS CO., LTD., Suwon-si (KR)

(72) Inventor: Seungmin KIM, Suwon-si (KR)

(73) Assignee: SAMSUNG ELECTRONICS CO., LTD., Suwon-si (KR)

(21) Appl. No.: 19/314,665

(22) Filed: Aug. 29, 2025

(30) Foreign Application Priority Data
Feb. 6, 2025 (KR) 10-2025-0015057

(51) Int. Cl. H10W 42/20; H10W 90/00; H10W 72/00; H10W 72/30; H10W 74/10; H10W 90/20; H10W 90/24; H10W 90/26

(52) U.S. Cl. CPC H10W 42/20; H10W 90/00; H10W 72/354; H10W 72/877; H10W 72/884; H10W 74/117; H10W 90/24; H10W 90/26; H10W 90/297; H10W 90/722; H10W 90/724; H10W 90/732; H10W 90/734; H10W 90/736; H10W 90/752; H10W 90/754

(57) ABSTRACT

A semiconductor package may include: a substrate; a semiconductor chip on a first surface of the substrate, wherein a lower surface of the semiconductor chip faces the first surface of the substrate; an organic material layer on an upper surface of the semiconductor chip; a mold layer on the first surface of the substrate and a side surface of the semiconductor chip, and extending onto a side surface of the organic material layer; and a shielding layer on the mold layer and the organic material layer, wherein an upper surface of the organic material layer is exposed from the mold layer, and wherein the shielding layer is on the upper surface of the organic material layer, and extends onto an upper surface of the mold layer, a side surface of the mold layer, and a side surface of the substrate.

### CROSS-REFERENCE TO RELATED APPLICATION

This U.S. non-provisional patent application claims priority under 35 U.S.C. §119 of Korean Patent Application No. 10-2025-0015057, filed on February 6, 2025, the disclosure of which is hereby incorporated by reference in its entirety.

### BACKGROUND

### 1. Field

Some embodiments of the present disclosure relate to a semiconductor package, and more particularly, to a semiconductor package having an electro-magnetic interference (EMI) shielding structure.

### 2. Description of Background Art

An integrated circuit chip may be packaged into a semiconductor package to have a suitable form to be installed in an electronic device. In general, in a semiconductor package, a semiconductor chip may be mounted on a printed circuit board (PCB), and the semiconductor chip and the PCB may be electrically connected to each other using bonding wires or bumps. Electronic devices may be required to have a small size, light weight, and multiple functions. To meet such requirements, a multi-chip package in which a plurality of chips are stacked in a single semiconductor package, a system-in package in which different types of chips are mounted in a single semiconductor package and operate as a single system, and the like are proposed.

Due to electro-magnetic interference (EMI) that may occur inside or outside a semiconductor package, semiconductor chips may malfunction. Accordingly, there is a need for a semiconductor package to have an EMI shielding structure to prevent such a malfunction.

### SUMMARY

According to some embodiments of the present disclosure, a semiconductor package that makes it possible to minimize a delamination defect in an electro-magnetic shielding layer and a method for manufacturing the same may be provided.

According to some embodiments of the present disclosure, a semiconductor package may include: a substrate; a semiconductor chip on a first surface of the substrate, wherein a lower surface of the semiconductor chip faces the first surface of the substrate; an organic material layer on an upper surface of the semiconductor chip; a mold layer on the first surface of the substrate and a side surface of the semiconductor chip, and extending onto a side surface of the organic material layer; and a shielding layer on the mold layer and the organic material layer, wherein an upper surface of the organic material layer is exposed from the mold layer, and wherein the shielding layer is on the upper surface of the organic material layer, and extends onto an upper surface of the mold layer, a side surface of the mold layer, and a side surface of the substrate.

According to some embodiments of the present disclosure, a semiconductor package may include: a substrate; a plurality of semiconductor chips stacked on a first surface of the substrate in a first direction perpendicular to the first surface; an organic material layer on an upper surface of an uppermost semiconductor chip among the plurality of semiconductor chips; a mold layer on the first surface of the substrate and side surfaces of the plurality of semiconductor chips, and extending onto a side surface of the organic material layer; and a shielding layer on the mold layer and the organic material layer, wherein the shielding layer is on an upper surface of the organic material layer and extends onto an upper surface of the mold layer, a side surface of the mold layer, and a side surface of the substrate.

According to some embodiments of the present disclosure, a semiconductor package may include: a substrate; a semiconductor chip on a first surface of the substrate; an organic material layer on an upper surface of the semiconductor chip; a mold layer on the first surface of the substrate and a side surface of the semiconductor chip, and extending onto a side surface of the organic material layer; a shielding layer on the mold layer and the organic material layer and extending onto a side surface of the substrate; and a plurality of solders horizontally spaced apart from each other on a second surface of the substrate, opposite to the first surface, wherein the shielding layer is connected, at the side surface of the substrate, to a ground line of the substrate.

According to some embodiments of the present disclosure, a semiconductor package having excellent reliability and a method for manufacturing the same may be provided.

### BRIEF DESCRIPTION OF DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view of a semiconductor package according to some embodiments of the present disclosure;

FIG. 2 is a cross-sectional view taken along a line A-A’ of FIG. 1;

FIGS. 3 to 6 are cross-sectional views, taken along the line A-A’ of FIG. 1, illustrating a method for manufacturing a semiconductor package according to some embodiments of the present disclosure;

FIGS. 7 to 9 are cross-sectional views, taken along the line A-A’ of FIG. 1, illustrating a semiconductor package according to some embodiments of the present disclosure;

FIG. 10 is a plan view of a semiconductor package according to some embodiments of the present disclosure;

FIG. 11 is a cross-sectional view taken along a line B-B’ of FIG. 10; and

FIG. 12 is a cross-sectional view of a semiconductor module including a semiconductor package according to some embodiments of the present disclosure.

### DETAILED DESCRIPTION

Hereinafter, non-limiting example embodiments of the present disclosure will be described in detail with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

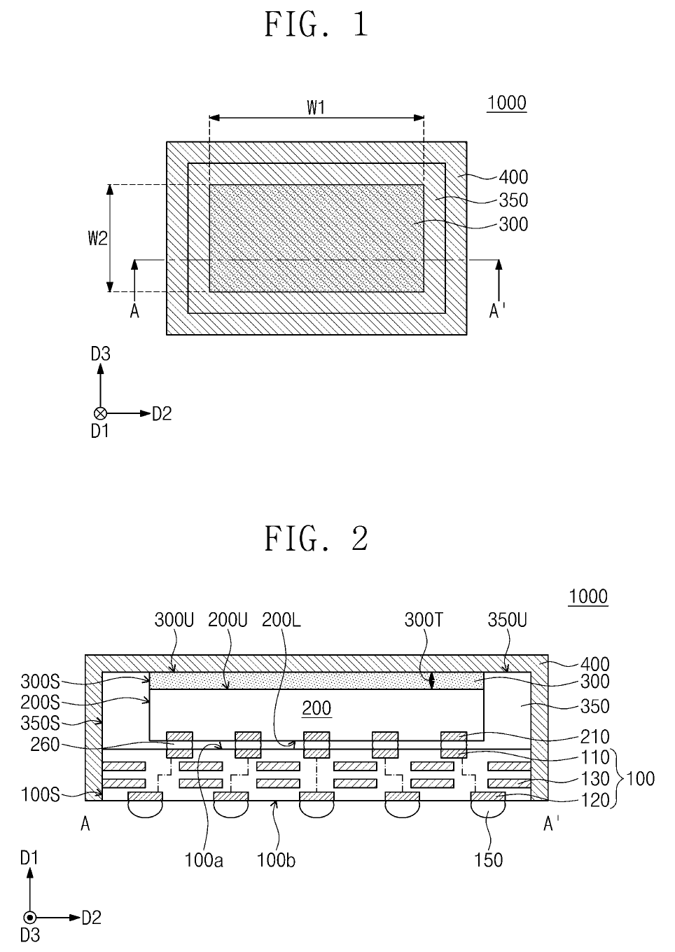

FIG. 1 is a plan view of a semiconductor package according to some embodiments of the present disclosure. FIG. 2 is a cross-sectional view taken along a line A-A’ of FIG. 1.

Referring to FIGS. 1 and 2, a semiconductor package 1000 may include a substrate 100, a semiconductor chip 200, an organic material layer 300, a mold layer 350, and a shielding layer 400.

The substrate 100 may have a first surface 100a and a second surface 100b opposite to each other. The substrate 100 may include first substrate pads 110 adjacent to the first surface 100a, second substrate pads 120 adjacent to the second surface 100b, and ground lines 130 disposed in the substrate 100. The first substrate pads 110 and the second substrate pads 120 may be electrically connected to each other through signal lines in the substrate 100. In the present disclosure, a first direction D1 may be a direction perpendicular to the first surface 100a and the second surface 100b of the substrate 100, and a second direction D2 and a third direction D3 may be directions parallel with the first surface 100a and the second surface 100b of the substrate 100 and intersecting each other. The first substrate pads 110 may be spaced apart from the second substrate pads 120 in the first direction D1. The first substrate pads 110 may be spaced apart from each other in the second direction D2 and the third direction D3. The second substrate pads 120 may be spaced apart from each other in the second direction D2 and the third direction D3. The first substrate pads 110, the second substrate pads 120, the ground lines 130, and the signal lines may include a conductive material (e.g., metal). According to some embodiments, the substrate 100 may be a printed circuit board (PCB).

The semiconductor package 1000 may further include a plurality of solders 150 disposed on the second surface 100b of the substrate 100. The plurality of solders 150 may be respectively disposed on the second substrate pads 120 and may be spaced apart from each other in a direction (e.g., the second direction D2 and/or the third direction D3) parallel to the second surface 100b. The plurality of solders 150 may include a conductive material, and may have a shape of at least one from among a solder ball, a bump, and a pillar.

The semiconductor chip 200 may be disposed on the first surface 100a of the substrate 100. The semiconductor chip 200 may have an upper surface 200U and a lower surface 200L opposite to each other in the first direction D1, and the lower surface 200L of the semiconductor chip 200 may face the first surface 100a of the substrate 100. The semiconductor chip 200 may include first chip pads 210 adjacent to the lower surface 200L. The first chip pads 210 may be spaced apart from each other in a direction (e.g., the second direction D2 and/or the third direction D3) parallel to the lower surface 200L and may be electrically connected to integrated circuits in the semiconductor chip 200. The first chip pads 210 may include a conductive material (e.g., metal). The semiconductor chip 200 may be any one from among a memory chip, a logic chip, an application processor (AP) chip, and a system on chip (SOC).

The semiconductor package 1000 may further include connection bumps 260 between the first surface 100a of the substrate 100 and the lower surface 200L of the semiconductor chip 200. The connection bumps 260 may be disposed on the lower surface 200L of the semiconductor chip 200 and on the first chip pads 210 respectively. The connection bumps 260 may be respectively connected to corresponding first substrate pads 110 among the first substrate pads 110. The semiconductor chip 200 may be electrically connected to the substrate 100 through the first chip pads 210, the connection bumps 260, and the first substrate pads 110. The connection bumps 260 may include a conductive material, and may have a shape of at least one from among a solder ball, a bump, and a pillar.

The organic material layer 300 may be disposed on the upper surface 200U of the semiconductor chip 200. The organic material layer 300 may cover an entirety of the upper surface 200U of the semiconductor chip 200. A side surface 300S of the organic material layer 300 and a side surface 200S of the semiconductor chip 200 may be aligned (e.g., coplanar) with each other in the first direction D1. The organic material layer 300 may have a first width W1 in the second direction D2 and a second width W2 in the third direction D3. The first width W1 may be about 300 μm to about 2000 μm, and the second width W2 may be about 300 μm to about 2000 μm. An aspect ratio (i.e., W1/W2) of the organic material layer 300 may be about 0.5 to about 2. The organic material layer 300 may have a thickness 300T in the first direction D1, and the thickness 300T of the organic material layer 300 may be about 80 μm to about 300 μm. A width of the semiconductor chip 200 in the second direction D2 may be the same as the first width W1, and a width of the semiconductor chip 200 in the third direction D3 may be the same as the second width W2. In a plan view, a size of the organic material layer 300 may be the same as a size of the semiconductor chip 200.

The organic material layer 300 may include a thermosetting resin. For example, the organic material layer 300 may include acrylic resin, epoxy resin, amino resin, phenol resin, polyester resin, polyurethane resin, or the like.

The mold layer 350 may be disposed on the first surface 100a of the substrate 100 and may cover the semiconductor chip 200 and the organic material layer 300. The mold layer 350 may cover the side surface 200S of the semiconductor chip 200 and may extend onto the side surface 300S of the organic material layer 300. According to some embodiments, the mold layer 350 may extend between the first surface 100a of the substrate 100 and the lower surface 200L of the semiconductor chip 200, and may fill a space between the connection bumps 260. According to other embodiments, an underfill layer may be interposed between the first surface 100a of the substrate 100 and the lower surface 200L of the semiconductor chip 200, and may fill a space between the connection bumps 260. In this case, the mold layer 350 may cover the underfill layer.

An upper surface 350U of the mold layer 350 may be positioned at a higher height than a height of the upper surface 200U of the semiconductor chip 200. In the present disclosure, a height may refer to a distance measured from the first surface 100a of the substrate 100 in the first direction D1. An upper surface 300U of the organic material layer 300 may be exposed from the mold layer 350. The upper surface 350U of the mold layer 350 may be positioned at the same height as a height of the upper surface 300U of the organic material layer 300. The upper surface 350U of the mold layer 350 and the upper surface 300U of the organic material layer 300 may be coplanar with each other. The mold layer 350 may include an epoxy molding compound (EMC).

The shielding layer 400 may be disposed on the organic material layer 300 and the mold layer 350. The shielding layer 400 may cover the upper surface 300U of the organic material layer 300 and may extend onto the upper surface 350U and the side surface 350S of the mold layer 350. The shielding layer 400 may extend onto a side surface 100S of the substrate 100 and may cover the side surface 100S of the substrate 100. The second surface 100b of the substrate 100 may be exposed from the shielding layer 400. The shielding layer 400 may be in contact with the upper surface 300U of the organic material layer 300, the upper surface 350U and the side surface 350S of the mold layer 350, and the side surface 100S of the substrate 100. Some of the ground lines 130 may be exposed through the side surface 100S of the substrate 100. The shielding layer 400 may be electrically connected to the ground lines 130 at the side surface 100S of the substrate 100.

The shielding layer 400 may include a conductive material. The shielding layer 400 may include metal. For example, the shielding layer 400 may have a multi-layer structure in which a surface of a metal layer is coated with stainless steel (SUS). For example, the shielding layer 400 may have a triple-layer structure of SUS-Cu-SUS. The shielding layer 400 may shield electro-magnetic interference that occurs inside or outside the semiconductor package 1000.

When the shielding layer 400 is in contact with the upper surface 200U of the semiconductor chip 200, an issue of floating and delamination of the shielding layer 400 may occur due to a weak adhesion between the shielding layer 400 and the semiconductor chip 200.

According to an embodiment of the present disclosure, the organic material layer 300 may be interposed between the upper surface 200U of the semiconductor chip 200 and the shielding layer 400. The shielding layer 400 may be in contact with the organic material layer 300 and the mold layer 350. The floating and delamination of the shielding layer 400 may be prevented due to a relatively strong adhesion between the shielding layer 400 and the organic material layer 300. In addition, a surface defect that may be present on the upper surface 200U of the semiconductor chip 200 may be covered with the organic material layer 300. Accordingly, a crack of the semiconductor chip 200 may be prevented, and a defect in an outer appearance of the semiconductor package 1000 may be resolved.

Therefore, a semiconductor package that makes it possible to minimize a delamination defect in an electro-magnetic shielding layer and has excellent reliability may be provided.

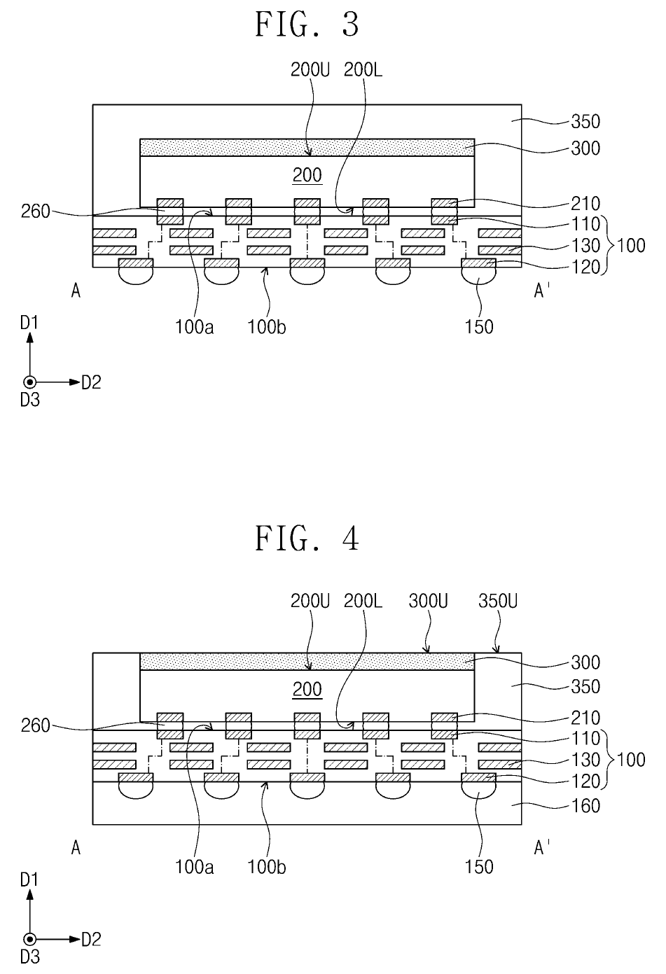

FIGS. 3 to 6 are cross-sectional views, taken along the line A-A’ of FIG. 1, illustrating a method for manufacturing a semiconductor package according to some embodiments of the present disclosure. For conciseness, descriptions overlapping with the above descriptions of the semiconductor package provided with reference to FIGS. 1 and 2 may not be repeated.

Referring to FIG. 3, the substrate 100 may be provided. The substrate 100 may have a first surface 100a and a second surface 100b opposite to each other. The substrate 100 may include first substrate pads 110 adjacent to the first surface 100a, second substrate pads 120 adjacent to the second surface 100b, and ground lines 130 disposed in the substrate 100. The first substrate pads 110 and the second substrate pads 120 may be electrically connected to each other through signal lines in the substrate 100. According to some embodiments, the substrate 100 may be a printed circuit board (PCB).

A chip structure including the semiconductor chip 200 and the organic material layer 300 may be provided. The semiconductor chip 200 may have an upper surface 200U and a lower surface 200L opposite to each other, and the organic material layer 300 may be disposed on the upper surface 200U of the semiconductor chip 200. Forming of the chip structure may include, for example, forming a substrate structure by forming a preliminary organic material layer on a wafer including a plurality of semiconductor chips 200, and separating the substrate structure into a plurality of chip structures by performing a dicing process. Each of the chip structures may include the semiconductor chip 200 and the organic material layer 300. The semiconductor chip 200 may include first chip pads 210 adjacent to the lower surface 200L. Connection bumps 260 may be disposed on the lower surface 200L of the semiconductor chip 200 and on the first chip pads 210 respectively.

The chip structure may be mounted on the first surface 100a of the substrate 100 so that the lower surface 200L of the semiconductor chip 200 faces the first surface 100a of the substrate 100. The connection bumps 260 may be respectively connected to corresponding first substrate pads 110 among the first substrate pads 110.

The mold layer 350 may be formed on the first surface 100a of the substrate 100 and may cover the semiconductor chip 200 and the organic material layer 300. The plurality of solders 150 may be formed on the second surface 100b of the substrate 100 and respectively disposed on the second substrate pads 120.

Referring to FIG. 4, a carrier film 160 may be formed on the second surface 100b of the substrate 100 and may cover the plurality of solders 150. For example, the carrier film 160 may be an ultraviolet (UV) tape.

A grinding process may be performed on the mold layer 350. The grinding process may be performed until the upper surface 300U of the organic material layer 300 is exposed. Due to the grinding process, the upper surface 350U of the mold layer 350 may be positioned at the same height as a height of the upper surface 300U of the organic material layer 300, and the upper surface 350U of the mold layer 350 may be coplanar with the upper surface 300U of the organic material layer 300. Since the organic material layer 300 is locally disposed on the upper surface 200U of the semiconductor chip 200, the upper surface 350U of the mold layer 350 may be positioned at a higher height than a height of the upper surface 200U of the semiconductor chip 200.

The substrate 100, the semiconductor chip 200, the organic material layer 300, the mold layer 350, the plurality of solders 150, the connection bumps 260, and the carrier film 160 may be referred to as a package structure.

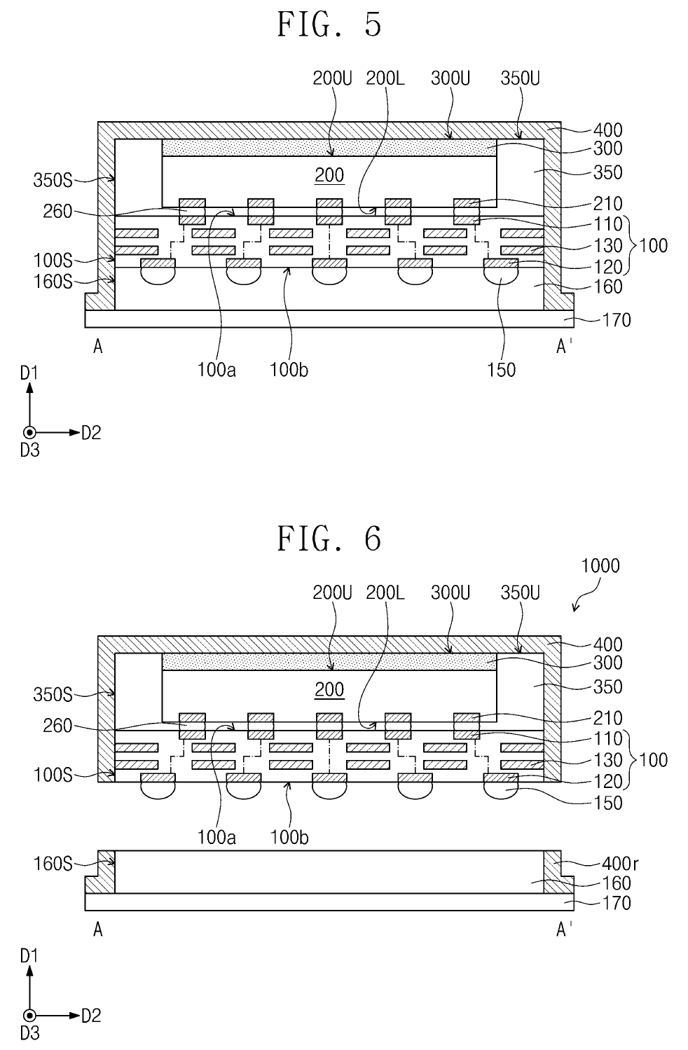

Referring to FIG. 5, the package structure may be provided on a support film 170. For example, the support film 170 may be a polyimide tape. The carrier film 160 may be attached to the support film 170, and thus the package structure may be fixed to the support film 170.

The shielding layer 400 may be formed on the package structure. The shielding layer 400 may be formed through a deposition process, which may be, for example, a sputtering deposition process. The shielding layer 400 may cover the upper surface 300U of the organic material layer 300 and may extend onto the upper surface 350U and the side surface 350S of the mold layer 350. The shielding layer 400 may extend onto a side surface 100S of the substrate 100 and may cover the side surface 100S of the substrate 100. The shielding layer 400 may extend onto a side surface 160S of the carrier film 160 and may cover the side surface 160S of the carrier film 160.

Referring to FIG. 6, the carrier film 160 may be separated from the second surface 100b of the substrate 100. A portion 400r of the shielding layer 400 may remain on the side surface 160S of the carrier film 160. The substrate 100, the semiconductor chip 200, the organic material layer 300, the mold layer 350, the plurality of solders 150, the connection bumps 260, and the shielding layer 400 may constitute the semiconductor package 1000. An adhesion between the carrier film 160 and the support film 170 may be higher than an adhesion between the carrier film 160 and the substrate 100. As the semiconductor package 1000 is lifted up, the semiconductor package 1000 may be separated from the carrier film 160.

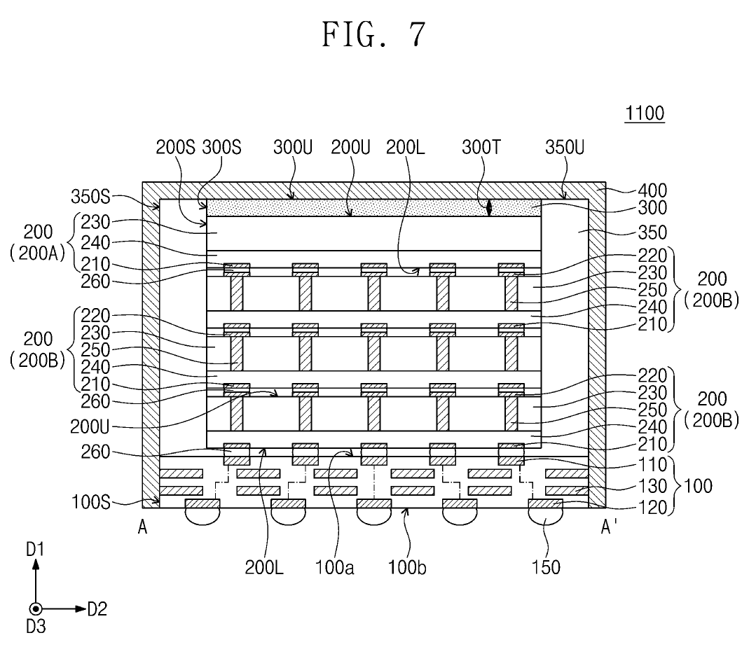

FIG. 7 is a cross-sectional view of a semiconductor package, taken along the line A-A’ of FIG. 1, according to some embodiments of the present disclosure. For conciseness, differences from the semiconductor package described with reference to FIGS. 1 and 2 will be mainly described.

Referring to FIGS. 1 and 7, a semiconductor package 1100 may include a substrate 100, a plurality of semiconductor chips 200, an organic material layer 300, a mold layer 350, and a shielding layer 400.

The substrate 100 may be substantially the same as the substrate 100 described with reference to FIGS. 1 and 2. The plurality of semiconductor chips 200 may be stacked on the first surface 100a of the substrate 100 in the first direction D1. The plurality of semiconductor chips 200 may each have an upper surface 200U and a lower surface 200L opposite to each other in the first direction D1, and the lower surface 200L of each of the plurality of semiconductor chips 200 may face towards the first surface 100a of the substrate 100.

According to some embodiments, each of the plurality of semiconductor chips 200 may each include a semiconductor substrate 230 and a circuit layer 240 on the semiconductor substrate 230. The circuit layer 240 may be adjacent to (e.g., define) the lower surface 200L of each of the plurality of semiconductor chips 200, and the semiconductor substrate 230 may be adjacent to (e.g., define) the upper surface 200U of each of the plurality of semiconductor chips 200. The semiconductor substrate 230 may be a silicon substrate, a germanium substrate, and/or a silicon-germanium substrate. The circuit layer 240 may include integrated circuits formed on the semiconductor substrate 230. The plurality of semiconductor chips 200 may each further include first chip pads 210 adjacent to the lower surface 200L of each of the plurality of semiconductor chips 200. The first chip pads 210 may be electrically connected to the circuit layer 240. The first chip pads 210 may include a conductive material (e.g., metal).

The plurality of semiconductor chips 200 may include an uppermost semiconductor chip 200A and lower semiconductor chips 200B stacked between the uppermost semiconductor chip 200A and the substrate 100 in the first direction D1. The lower semiconductor chips 200B may each further include through-chip electrodes 250 penetrating the semiconductor substrate 230, and second chip pads 220 disposed on the upper surface 200U of each of the lower semiconductor chips 200B and respectively connected to the through-chip electrodes 250. The through-chip electrodes 250 may each penetrate the semiconductor substrate 230 in the first direction D1. The through-chip electrodes 250 may be spaced apart from each other horizontally (e.g., in the second direction D2) in the semiconductor substrate 230 and may be electrically connected to the circuit layer 240. The through-chip electrodes 250 may include a conductive material (e.g., metal). The second chip pads 220 may be electrically connected to the circuit layer 240 through the through-chip electrodes 250. The second chip pads 220 may include a conductive material (e.g., metal). The uppermost semiconductor chip 200A may not include the through-chip electrodes 250 and the second chip pads 220.

Connection bumps 260 may be disposed on the lower surface 200L of each of the plurality of semiconductor chips 200 and on the first chip pads 210 respectively. The connection bumps 260 may include a conductive material, and may have a shape of at least one from among a solder ball, a bump, and a pillar. The connection bumps 260 may be disposed between the substrate 100 and a lowermost one of the lower semiconductor chips, and may be respectively connected to corresponding first substrate pads 110 among the first substrate pads 110. The connection bumps 260 may be disposed between the plurality of semiconductor chips 200 and may be respectively connected to the second chip pads 220 of the lower semiconductor chips 200B. The plurality of semiconductor chips 200 may be electrically connected to each other through the connection bumps 260 and electrically connected to the substrate 100. The uppermost semiconductor chip 200A may be electrically connected to the substrate 100 through the lower semiconductor chips 200B. The plurality of semiconductor chips 200 may each be any one from among a memory chip, a logic chip, an application processor (AP) chip, and a system on chip (SOC).

The organic material layer 300 may be disposed on the upper surface 200U of the uppermost semiconductor chip 200A. The organic material layer 300 may cover an entirety of the upper surface 200U of the uppermost semiconductor chip 200A. A side surface 300S of the organic material layer 300 and a side surface 200S of the uppermost semiconductor chip 200A may be aligned (e.g., coplanar) with each other in the first direction D1. The organic material layer 300 may be substantially the same as the organic material layer 300 described with reference to FIGS. 1 and 2. A width of the uppermost semiconductor chip 200A in the second direction D2 may be the same as the first width W1 of the organic material layer 300, and a width of the uppermost semiconductor chip 200A in the third direction D3 may be the same as the second width W2 of the organic material layer 300. In a plan view, a size of the organic material layer 300 may be the same as a size of the uppermost semiconductor chip 200A.

The mold layer 350 may be disposed on the first surface 100a of the substrate 100 and may cover the plurality of semiconductor chips 200 and the organic material layer 300. The mold layer 350 may cover the side surfaces 200S of the plurality of semiconductor chips 200 and may extend onto the side surface 300S of the organic material layer 300. According to some embodiments, the mold layer 350 may extend between the first surface 100a of the substrate 100 and the lower surface 200L of the lowermost one of the lower semiconductor chips 200B and between the plurality of semiconductor chips 200, and may fill a space between the connection bumps 260.

An upper surface 350U of the mold layer 350 may be positioned at a higher height than a height of the upper surface 200U of the uppermost semiconductor chip 200A. An upper surface 300U of the organic material layer 300 may be exposed from the mold layer 350. The upper surface 350U of the mold layer 350 may be positioned at the same height as a height of the upper surface 300U of the organic material layer 300. The upper surface 350U of the mold layer 350 and the upper surface 300U of the organic material layer 300 may be coplanar with each other.

The shielding layer 400 may be disposed on the organic material layer 300 and the mold layer 350. The shielding layer 400 may cover the upper surface 300U of the organic material layer 300 and may extend onto the upper surface 350U and the side surface 350S of the mold layer 350. The shielding layer 400 may extend onto a side surface 100S of the substrate 100 and may cover the side surface 100S of the substrate 100. The second surface 100b of the substrate 100 may be exposed from the shielding layer 400. The shielding layer 400 may be electrically connected to the ground lines 130 of the substrate 100 at the side surface 100S of the substrate 100.

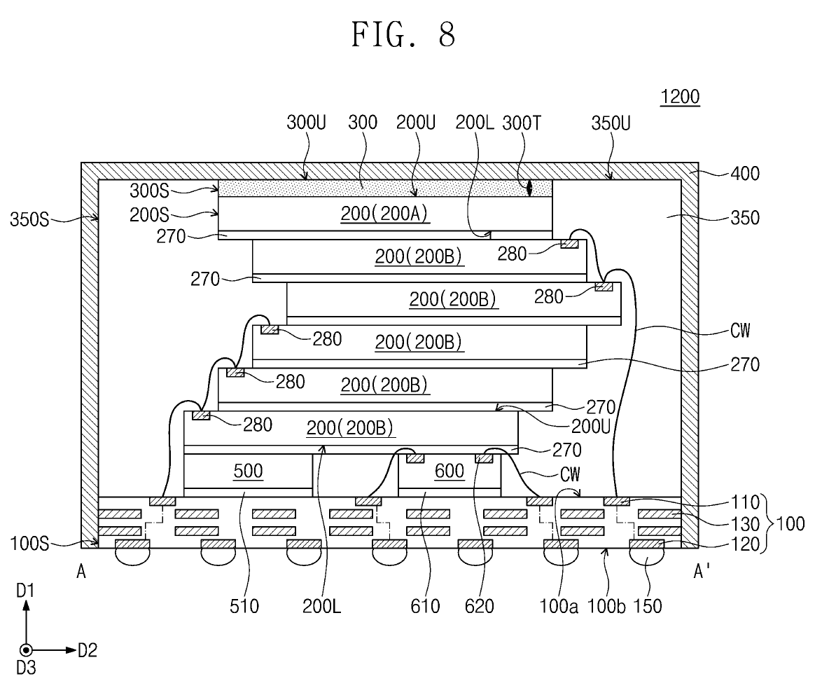

FIG. 8 is a cross-sectional view of a semiconductor package, taken along the line A-A’ of FIG. 1, according to some embodiments of the present disclosure. For conciseness, differences from the semiconductor package described with reference to FIGS. 1 and 2 will be mainly described.

Referring to FIGS. 1 and 8, a semiconductor package 1200 may include a substrate 100, a plurality of semiconductor chips 200, an organic material layer 300, a mold layer 350, and a shielding layer 400.

The substrate 100 may be substantially the same as the substrate 100 described with reference to FIGS. 1 and 2. The plurality of semiconductor chips 200 may be stacked on the first surface 100a of the substrate 100 in the first direction D1. The plurality of semiconductor chips 200 may each have an upper surface 200U and a lower surface 200L opposite to each other in the first direction D1, and the lower surface 200L of each of the plurality of semiconductor chips 200 may face towards the first surface 100a of the substrate 100.

According to some embodiments, the plurality of semiconductor chips 200 may be stacked so as to have a stepped structure. Non-conductive films (NCF) 270 may be disposed on the lower surfaces 200L of the plurality of semiconductor chips 200. The non-conductive films 270 may include an insulating material.

The plurality of semiconductor chips 200 may include an uppermost semiconductor chip 200A and lower semiconductor chips 200B stacked between the uppermost semiconductor chip 200A and the substrate 100 in the first direction D1. The lower semiconductor chips 200B may each further include conductive pads 280 adjacent to the upper surface 200U of each of the lower semiconductor chips 200B. The conductive pads 280 may include a conductive material (e.g., metal). The semiconductor package 1200 may further include conductive wires CW, and the conductive wires CW may electrically connect the conductive pads 280 of the lower semiconductor chips 200B to the first substrate pads 110 of the substrate 100. The lower semiconductor chips 200B may be electrically connected to the substrate 100 through the conductive wires CW. The uppermost semiconductor chip 200A may not include the conductive pads 280. The uppermost semiconductor chip 200A may be a dummy semiconductor chip (or mirror chip) electrically separated from the lower semiconductor chips 200B and the substrate 100. The lower semiconductor chips 200B may each be any one from among a memory chip, a logic chip, an application processor (AP) chip, and a system on chip (SOC).

According to some embodiments, the semiconductor package 1200 may further include a first semiconductor chip 500 and a second semiconductor chip 600 mounted on the first surface 100a of the substrate 100. The first semiconductor chip 500 and the second semiconductor chip 600 may be disposed between the substrate 100 and the lowermost one of the lower semiconductors chip 200B. The first semiconductor chip 500 and the second semiconductor chip 600 may be spaced apart from each other horizontally (e.g., in the second direction D2).

A first adhesive layer 510 may be interposed between the first semiconductor chip 500 and the substrate 100. The first semiconductor chip 500 may be mounted on the substrate 100 by the first adhesive layer 510. The first semiconductor chip 500 may be, for example, a dummy chip for supporting the plurality of semiconductor chips 200, but an embodiment of the present disclosure is not limited thereto. A second adhesive layer 610 may be interposed between the second semiconductor chip 600 and the substrate 100. The second semiconductor chip 600 may be mounted on the substrate 100 by the second adhesive layer 610. The second semiconductor chip 600 may include connection pads 620, and the connection pads 620 may include a conductive material (e.g., metal). The conductive wires CW may electrically connect the connection pads 620 of the second semiconductor chip 600 to the first substrate pads 110 of the substrate 100. The second semiconductor chip 600 may be electrically connected to the substrate 100 through the conductive wires CW. The second semiconductor chip 600 may be a controller chip for controlling the plurality of semiconductor chips 200, but an embodiment of the present disclosure is not limited thereto.

The organic material layer 300 may be disposed on the upper surface 200U of the uppermost semiconductor chip 200A. The organic material layer 300 may cover an entirety of the upper surface 200U of the uppermost semiconductor chip 200A. A side surface 300S of the organic material layer 300 and a side surface 200S of the uppermost semiconductor chip 200A may be aligned (e.g., coplanar) with each other in the first direction D1. The organic material layer 300 may be substantially the same as the organic material layer 300 described with reference to FIGS. 1 and 2. A width of the uppermost semiconductor chip 200A in the second direction D2 may be the same as the first width W1 of the organic material layer 300, and a width of the uppermost semiconductor chip 200A in the third direction D3 may be the same as the second width W2 of the organic material layer 300. In a plan view, a size of the organic material layer 300 may be the same as a size of the uppermost semiconductor chip 200A.

The mold layer 350 may be disposed on the first surface 100a of the substrate 100 and may cover the first semiconductor chip 500, the second semiconductor chip 600, the plurality of semiconductor chips 200, and the organic material layer 300. The mold layer 350 may cover side surfaces of the first semiconductor chip 500 and the second semiconductor chip 600 and the side surfaces 200S of the plurality of semiconductor chips 200, and may extend onto the side surface 300S of the organic material layer 300. An upper surface 350U of the mold layer 350 may be positioned at a higher height than a height of the upper surface 200U of the uppermost semiconductor chip 200A. An upper surface 300U of the organic material layer 300 may be exposed from the mold layer 350. The upper surface 350U of the mold layer 350 may be positioned at the same height as the upper surface 300U of the organic material layer 300. The upper surface 350U of the mold layer 350 and the upper surface 300U of the organic material layer 300 may be coplanar with each other.

The shielding layer 400 may be disposed on the organic material layer 300 and the mold layer 350. The shielding layer 400 may cover the upper surface 300U of the organic material layer 300 and may extend onto the upper surface 350U and the side surface 350S of the mold layer 350. The shielding layer 400 may extend onto a side surface 100S of the substrate 100 and may cover the side surface 100S of the substrate 100. The second surface 100b of the substrate 100 may be exposed from the shielding layer 400. The shielding layer 400 may be electrically connected to the ground lines 130 of the substrate 100 at the side surface 100S of the substrate 100.

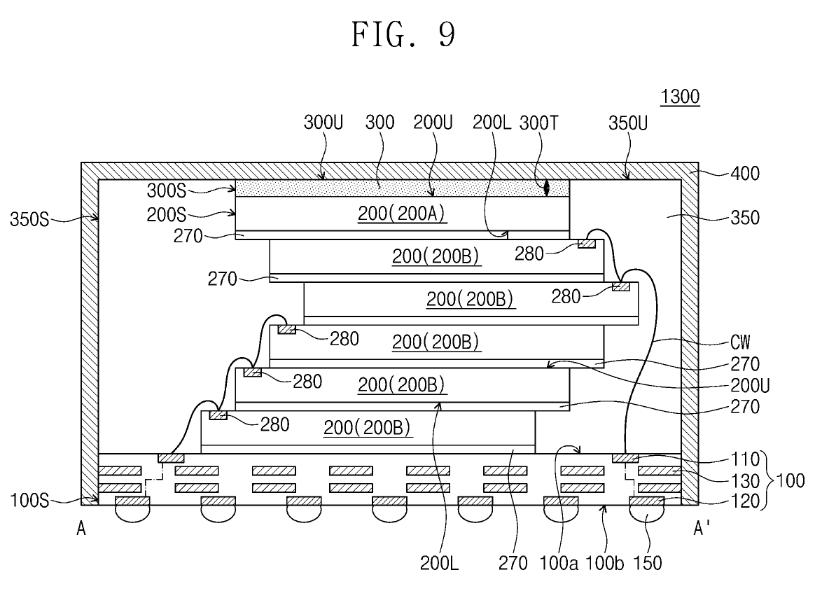

FIG. 9 is a cross-sectional view of a semiconductor package, taken along the line A-A’ of FIG. 1, according to some embodiments of the present disclosure. For conciseness, differences from the semiconductor package described with reference to FIGS. 1 and 2 will be mainly described.

Referring to FIGS. 1 and 9, a semiconductor package 1300 may be substantially the same as the semiconductor package 1200 described with reference to FIGS. 1 and 8 but may not include the first semiconductor chip 500, the second semiconductor chip 600, the first adhesive layer 510, and the second adhesive layer 610. According to the present embodiment, the lowermost one of the lower semiconductor chips 200B may be mounted on the substrate 100 by the non-conductive film 270 on the lower surface 200L of the lowermost one of the lower semiconductor chips 200B. The non-conductive film 270 on the lower surface 200L of the lowermost one of the lower semiconductor chips 200B may be in contact with the first surface 100a of the substrate 100.

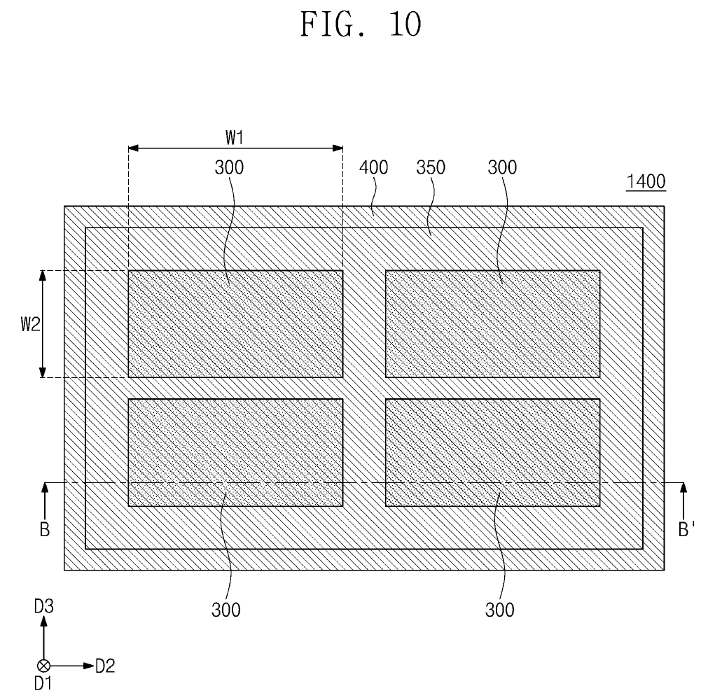

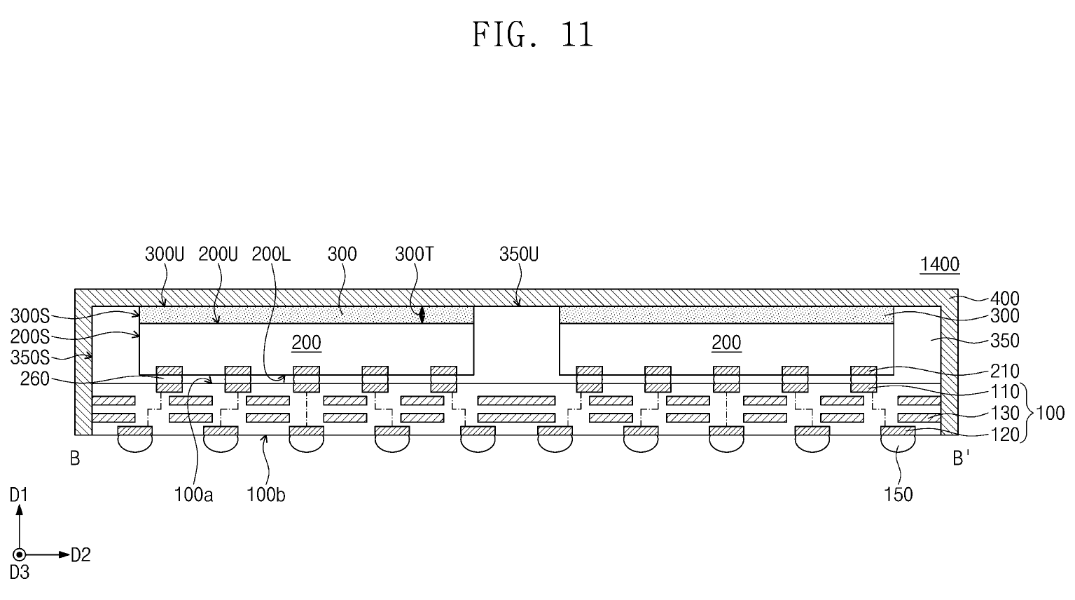

FIG. 10 is a plan view of a semiconductor package according to some embodiments of the present disclosure. FIG. 11 is a cross-sectional view taken along a line B-B’ of FIG. 10. For conciseness, differences from the semiconductor package described with reference to FIGS. 1 and 2 will be mainly described.

Referring to FIGS. 10 and 11, a semiconductor package 1400 may include a substrate 100, a plurality of semiconductor chips 200, a plurality of organic material layers 300, a mold layer 350, and a shielding layer 400.

The substrate 100 may be substantially the same as the substrate 100 described with reference to FIGS. 1 and 2. The plurality of semiconductor chips 200 may be mounted on the first surface 100a of the substrate 100 and may be spaced apart from each other in a direction (e.g., the second direction D2 and/or the third direction D3) parallel to the first surface 100a of the substrate 100. Although the number of the plurality of semiconductor chips 200 is illustrated as four, an embodiment of the present disclosure is not limited thereto.

The plurality of organic material layers 300 may be respectively disposed on the upper surfaces 200U of the plurality of semiconductor chips 200. Each of the organic material layers 300 may cover an entirety of the upper surface 200U of a respective one of the semiconductor chips 200. The side surface 200S of each of the semiconductor chips 200 and the side surface 300S of each of the organic material layers 300 may be aligned (e.g., coplanar) with each other in the first direction D1. Each of the plurality of organic material layers 300 may have the first width W1 in the second direction and the second width W2 in the third direction D3. A width of each of the plurality of semiconductor chips 200 in the second direction D2 may be the same as the first width W1 of a corresponding organic material layer 300, and a width of each of the plurality of semiconductor chips 200 in the third direction D3 may be the same as the second width W2 of a corresponding organic material layer 300. In a plan view, a size of each of the plurality of semiconductor chips 200 may be the same as a size of a corresponding organic material layer 300.

The mold layer 350 may be disposed on the first surface 100a of the substrate 100 and may cover the plurality of semiconductor chips 200 and the plurality of organic material layers 300. The mold layer 350 may cover the side surfaces 200S of the plurality of semiconductor chips 200 and may extend onto the side surfaces 300S of the plurality of organic material layers 300. An upper surface 350U of the mold layer 350 may be positioned at a higher height than a height of the upper surfaces 200U of the plurality of semiconductor chips 200. Upper surfaces 300U of the plurality of organic material layers 300 may be exposed from the mold layer 350. The upper surface 350U of the mold layer 350 may be positioned at the same height as a height of the upper surfaces 300U of the plurality of organic material layers 300. The upper surface 350U of the mold layer 350 and the upper surfaces 300U of the plurality of organic material layers 300 may be coplanar with each other.

The shielding layer 400 may be disposed on the plurality of organic material layers 300 and the mold layer 350. The shielding layer 400 may cover the upper surfaces 300U of the plurality of organic material layers 300 and may extend onto the upper surface 350U and the side surface 350S of the mold layer 350. The shielding layer 400 may extend onto a side surface 100S of the substrate 100 and may cover the side surface 100S of the substrate 100. The second surface 100b of the substrate 100 may be exposed from the shielding layer 400. The shielding layer 400 may be electrically connected to the ground lines 130 of the substrate 100 at the side surface 100S of the substrate 100.

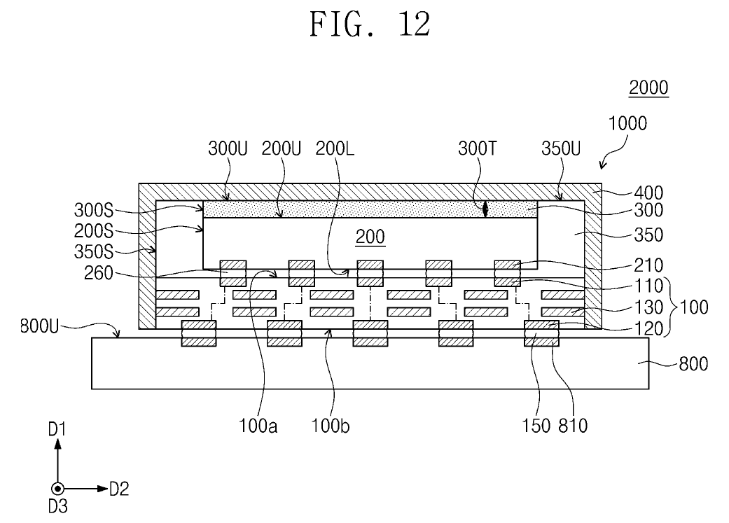

FIG. 12 is a cross-sectional view of a semiconductor module including a semiconductor package according to some embodiments of the present disclosure. For conciseness, descriptions overlapping with the above descriptions of the semiconductor package provided with reference to FIGS. 1 and 2 may not be repeated.

Referring to FIG. 12, a semiconductor module 2000 may include a module substrate 800 and a semiconductor package 1000 mounted on the module substrate 800. The semiconductor package 1000 may be substantially the same as the semiconductor package 1000 described with reference to FIGS. 1 and 2. According to some embodiments, the semiconductor package 1000 may be configured in substantially the same manner as the semiconductor packages 1100, 1200, 1300, and 1400 described with reference to FIGS. 7 to 11.

The module substrate 800 may be a printed circuit board. The module substrate 800 may include upper pads 810 adjacent to an upper surface 800U of the module substrate 800, and the upper pads 810 may be electrically connected to circuit patterns in the module substrate 800. The upper pads 810 may include a conductive material (e.g., metal).

The semiconductor package 1000 may be mounted on the upper surface 800U of the module substrate 800. The second surface 100b of the substrate 100 of the semiconductor package 1000 may face the upper surface 800U of the module substrate 800 and may be spaced apart from the upper surface 800U of the module substrate 800 vertically (e.g., in the first direction D1). The plurality of solders 150 of the semiconductor package 1000 may be disposed between the second surface 100b of the substrate 100 and the upper surface 800U of the module substrate 800 and may be respectively connected to the upper pads 810. The semiconductor package 1000 may be electrically connected to the module substrate 800 through the plurality of solders 150 and the upper pads 810. The shielding layer 400 of the semiconductor package 1000 may be spaced apart from the upper surface 800U of the module substrate 800 vertically (e.g., in the first direction D1).

According to embodiments of the present disclosure, an organic material layer may be locally formed on an upper surface of a semiconductor chip and may be interposed between the upper surface of the semiconductor chip and a shielding layer. Floating and delamination of the shielding layer may be prevented due to a relatively strong adhesion between the shielding layer and the organic material layer. In addition, a surface defect that may be present on the upper surface of the semiconductor chip may be covered with the organic material layer. Accordingly, a crack of the semiconductor chip may be prevented, and the surface defect on the upper surface of the semiconductor chip is not exposed to the outside of a semiconductor package, and thus a defect in an outer appearance of the semiconductor package may be prevented.

Therefore, a semiconductor package that makes it possible to minimize a delamination defect in an electro-magnetic shielding layer and has excellent reliability and a method for manufacturing the same may be provided.

According to some embodiments of the present disclosure, a method of manufacturing a semiconductor package may include: providing a chip structure on a first surface of a substrate, wherein the chip structure includes: a semiconductor chip, wherein a lower surface of the semiconductor chip faces the first surface of the substrate; and an organic material layer on an upper surface of the semiconductor chip; providing a mold layer on the first surface of the substrate and a side surface of the semiconductor chip, the mold layer extending onto a side surface of the organic material layer; and providing a shielding layer on the mold layer and the organic material layer, wherein an upper surface of the organic material layer is exposed from the mold layer, and wherein the shielding layer is on the upper surface of the organic material layer, and extends onto an upper surface of the mold layer, a side surface of the mold layer, and a side surface of the substrate In an embodiment, the shielding layer may be formed using a deposition process.

In an embodiment, the substrate may have the first surface and a second surface opposite to each other, and the chip structure may be mounted on the first surface of the substrate. In an embodiment, the method may further include forming a plurality of solders spaced apart from each other horizontally on the second surface of the substrate.

In an embodiment, the substrate may include a ground line provided therein, and the shielding layer may be connected to the ground line at the side surface of the substrate.

In an embodiment, the organic material layer may include a thermosetting resin.

In an embodiment, the shielding layer may include a conductive material.

In an embodiment, a side surface of the semiconductor chip and a side surface of the organic material layer may be aligned with each other in a direction perpendicular to the upper surface of the semiconductor chip.

In an embodiment, the shielding layer may be formed using sputtering deposition.

In an embodiment, the chip structure may further include a plurality of lower semiconductor chips stacked on the lower surface of the semiconductor chip. In an embodiment, the plurality of lower semiconductor chips may be stacked in a direction perpendicular to the lower surface of the semiconductor chip.

In an embodiment, the substrate may have the first surface and a second surface opposite to each other, and the chip structure may be mounted on the first surface of the substrate. The forming of the shielding layer may include: forming a carrier film on the second surface of the substrate; attaching a package structure including the substrate, the chip structure, the mold layer, and the carrier film to a support film; forming the shielding layer by performing the deposition process; and separating the carrier film from the second surface of the substrate.

In an embodiment, an upper surface of the mold layer may be positioned at the same height as the upper surface of the organic material layer through a grinding process.

Non-limiting example embodiments of the present disclosure are described above with reference to the accompanying drawings. Therefore, the present disclosure is not limited to the above example embodiments, and it would be understood by those skilled in the art that various modifications and changes may be provided by combining the above embodiments, and that the various modifications and changes are included within the spirit and scope of the present disclosure.

What is claimed is:

1. A semiconductor package comprising:
a substrate;
a semiconductor chip on a first surface of the substrate, wherein a lower surface of the semiconductor chip faces the first surface of the substrate;
an organic material layer on an upper surface of the semiconductor chip;
a mold layer on the first surface of the substrate and a side surface of the semiconductor chip, and extending onto a side surface of the organic material layer; and
a shielding layer on the mold layer and the organic material layer,
wherein an upper surface of the organic material layer is exposed from the mold layer, and wherein the shielding layer is on the upper surface of the organic material layer, and extends onto an upper surface of the mold layer, a side surface of the mold layer, and a side surface of the substrate.

2. The semiconductor package of claim 1, wherein the shielding layer is connected, at the side surface of the substrate, to a ground line of the substrate.

3. The semiconductor package of claim 1, wherein a height of the upper surface of the mold layer is higher than a height of the upper surface of the semiconductor chip.

4. The semiconductor package of claim 3, wherein the height of the upper surface of the mold layer is the same as a height of the upper surface of the organic material layer.

5. The semiconductor package of claim 1, wherein the shielding layer is in contact with the upper surface of the organic material layer, the upper surface of the mold layer, the side surface of the mold layer, and the side surface of the substrate.

6. The semiconductor package of claim 1, wherein the organic material layer comprises a thermosetting resin.

7. The semiconductor package of claim 1, wherein the shielding layer comprises a conductive material.

8. The semiconductor package of claim 1, further comprising a plurality of solders on a second surface of the substrate, opposite to the first surface, the plurality of solders horizontally spaced apart from each other.

9. The semiconductor package of claim 1, wherein the side surface of the semiconductor chip and the side surface of the organic material layer are aligned with each other in a direction perpendicular to the first surface of the substrate.

10. A semiconductor package comprising:
a substrate;
a plurality of semiconductor chips stacked on a first surface of the substrate in a first direction perpendicular to the first surface;
an organic material layer on an upper surface of an uppermost semiconductor chip among the plurality of semiconductor chips;
a mold layer on the first surface of the substrate and side surfaces of the plurality of semiconductor chips, and extending onto a side surface of the organic material layer; and
a shielding layer on the mold layer and the organic material layer,
wherein the shielding layer is on an upper surface of the organic material layer and extends onto an upper surface of the mold layer, a side surface of the mold layer, and a side surface of the substrate.

11. The semiconductor package of claim 10, wherein the shielding layer is connected, at the side surface of the substrate, to a ground line of the substrate.

12. The semiconductor package of claim 11, further comprising a plurality of solders on a second surface of the substrate, opposite to the first surface, the plurality of solders spaced apart from each other in a second direction parallel to the second surface.

13. The semiconductor package of claim 10, wherein a height of the upper surface of the mold layer is higher than a height of the upper surface of the uppermost semiconductor chip.

14. The semiconductor package of claim 13, wherein the height of the upper surface of the mold layer is the same as a height of the upper surface of the organic material layer.

15. The semiconductor package of claim 10, wherein a side surface of the uppermost semiconductor chip and the side surface of the organic material layer are aligned with each other in the first direction.

16. The semiconductor package of claim 10, wherein the plurality of semiconductor chips comprise lower semiconductor chips stacked between the uppermost semiconductor chip and the substrate in the first direction, and
wherein the lower semiconductor chips are electrically connected to the substrate.

17. The semiconductor package of claim 16, wherein the uppermost semiconductor chip is electrically connected to the substrate through the lower semiconductor chips.

18. The semiconductor package of claim 16, wherein the uppermost semiconductor chip comprises a dummy semiconductor chip electrically separated from the lower semiconductor chips.

19. A semiconductor package comprising:
a substrate;
a semiconductor chip on a first surface of the substrate;
an organic material layer on an upper surface of the semiconductor chip;
a mold layer on the first surface of the substrate and a side surface of the semiconductor chip, and extending onto a side surface of the organic material layer;
a shielding layer on the mold layer and the organic material layer and extending onto a side surface of the substrate; and
a plurality of solders horizontally spaced apart from each other on a second surface of the substrate, opposite to the first surface,
wherein the shielding layer is connected, at the side surface of the substrate, to a ground line of the substrate.

20. The semiconductor package of claim 19, wherein the organic material layer comprises a thermosetting resin.
